(19) United States
(12) Patent Application Publication
(10) Pub. No.: US 2022/0259493 A1
(43) Pub. Date: Aug. 18, 2022

(54) SOLAR WAVELENGTH CONVERSION MATERIAL, SOLAR CELL ENCAPSULANT COMPRISING SAME, AND SOLAR CELL COMPRISING SAME

(71) Applicant: HANWHA TOTAL PETROCHEMICAL CO., LTD., Seosan-si (KR)

(72) Inventors: Ki Se KIM, Seosan-si (KR); Jae Hyuck HAN, Seosan-si (KR); Do Hoon LEE, Seosan-si (KR); Choon Ki KIM, Seosan-si (KR); Young Rae KIM, Seosan-si (KR); Taejong PAIK, Seoul (KR); Min Hye KIM, Seoul (KR); Hyo Joo SHIN, Seosan-si (KR)

(21) Appl. No.: 17/625,281

(22) PCT Filed: Jul. 15, 2020
(86) PCT No.: PCT/KR2020/009280

§ 371 Date: Jan. 6, 2022

(30) Foreign Application Priority Data
Jul. 15, 2019 (KR) 10-2019-0085176
Aug. 1, 2019 (KR) 10-2019-0093929
Aug. 1, 2019 (KR) 10-2019-0093942

(51) Int. Cl. C09K 11/64; H01L 31/055; H01L 31/048; C09K 11/77; C09K 11/02; C01F 7/30; C01F 17/34; C08J 5/18; C08K 3/22

(52) U.S. Cl. CPC C09K 11/641; C08J 2323/08; H01L 31/0481; C09K 11/7706; C09K 11/02; C01F 7/30; C01F 17/34; C08J 5/18; C08K 3/22; C01P 2004/64; C01P 2004/62; C01P 2004/61; C08K 2003/2227; C08K 2201/005; C08K 2201/011; H01L 31/055

(57) ABSTRACT

The present invention relates to a solar wavelength conversion material with improved efficiency, and a solar cell comprising same. According to one embodiment of the present invention, the present invention provides a solar wavelength conversion material comprising an aluminum hydroxide precursor, and a lanthanide ion or a derivative containing same.

### RELATED APPLICATION DATA

This application claims the benefit of each of Korean Patent Application No. 10-2019-0085176 filed on Jul. 15, 2019, Korean Patent Application No. 10-2019-0093942 filed on Aug. 1, 2019, and Korean Patent Application No. 10-2019-0093929 filed on Aug. 1, 2019, the disclosures of which are incorporated herein by reference in their entireties.

### TECHNICAL FIELD

The present invention relates to a solar wavelength conversion material with improved efficiency, and a solar cell encapsulant and a solar cell, comprising same.

### BACKGROUND ART

The most commonly commercialized solar cells are made of a silicon material, and about 50% of the light cannot be used due to the mismatch between the natural sunlight spectrum and the band gap of the silicon based material. That is, the natural sunlight spectrum has a wide distribution (280-2500 nm, 0.5-4.4 eV) from ultraviolet to infrared wavelengths, whereas silicon solar cells can absorb only some wavelengths of ultraviolet and visible wavelengths.

Recently, in order to compensate for this, studies using a solar wavelength conversion material have been proposed to improve the photocurrent conversion efficiencies of natural sunlight and silicon solar cells (Chem. Soc. Rev., 2013, 42, 173). That is, the proposed studies is to introduce a solar wavelength conversion material (solar spectral converter) to a silicon solar cell, the solar wavelength conversion material converting the light in in the ultraviolet region where silicon absorbs sunlight is insufficient or in the infrared region having smaller energy than the silicon bandgap into the light in visible or near-infrared light wavelength regions where the visible or near-infrared light can be absorbed well by silicon.

In addition, since solar cells or solar modules which generally consist of solar cells are installed outdoors and are exposed to external environments, such as heat, moisture, diurnal range, or pollution sources, for a long time, it is essential to secure long-term durability so as not to be affected by these external factors.

In order to solve the above problems, a functional additive may also be dispersed in an encapsulant. For example, the long-term durability may be secured by adding to the encapsulant, a UV stabilizer, a UV absorber, or a combination of an absorber and a stabilizer, which may be added to improve the durability against UV rays.

However, in the case of a ultraviolet absorber, the light in the vicinity of a ultraviolet region cannot be incident into a solar cell, and thus the overall initial output of a solar cell module may be undesirably lowered. In addition, in order to improve insulation or induce moisture capture, when inorganic particles such as silica or magnesium hydroxide are introduced, the durability of the encapsulant may be more or less improved, but light absorption of the solar cell may be disturbed due to scattering or reflection of the sunlight incident into the front surface of the solar cell. As such, when a plurality of functional additives are added to solve the above problems, the durability of the encapsulant may be improved, but the overall output of a solar cell or solar cell module may be lowered.

### DESCRIPTION OF EMBODIMENTS

### Technical Problem

To solve the above problems, an objective of the present invention is to provide a solar conversion material capable of improving the photocurrent conversion efficiency of a solar cell.

Another objective of the present invention to provide a solar cell encapsulant, and a solar cell having high durability while having excellent photocurrent conversion efficiency.

### Solution to Problem

To achieve an objective of the present invention, the present invention provides a solar wavelength conversion material comprising a luminescent aluminum hydroxide precursor.

According to an embodiment, the aluminum hydroxide precursor is preferably any one of aluminum monoacetate, aluminum triacetate, aluminum diacetate, triethyl aluminum, trimethyl aluminum, aluminum alkoxide, diethyl aluminum chloride, aluminum sulfate, aluminum cyanide, aluminum nitrite, aluminum carbonate, aluminum sulfite, aluminum hydroxide, aluminum oxide, aluminum chlorate, aluminum sulfide, aluminum chromate, aluminum trichloride, aluminum perchlorate, aluminum nitrate, aluminum permanganate, aluminum hydrogen carbonate, aluminum phosphate, aluminum oxalate, aluminum hydrogen phosphate, aluminum thiosulfate, aluminum chlorite, aluminum hydrogen sulfate, aluminum dichromate, aluminum bromide, aluminum hypochlorite, aluminum chloride hexahydrate, aluminum dihydrogen phosphate, aluminum phosphite, aluminum potassium sulfate dodeca hydrate, aluminum bromate, aluminum nitride, or derivatives thereof.

According to an embodiment, the solar wavelength conversion material preferably includes an Al(OH)₃, AlOOH, 5Al₂O₃.2H₂O, or Al₂O₃ structure.

According to an embodiment, the luminescent aluminum hydroxide preferably has a size in a range of 1 nm to 1000 μm.

According to an embodiment, the luminescent aluminum hydroxide preferably has a porous structure.

According to an embodiment, the solar wavelength conversion material preferably further comprises a lanthanide ion or a derivative containing same.

According to an embodiment, the lanthanide ion is preferably capable of emitting light in a near-infrared, ultraviolet, or visible light wavelength region.

According to an embodiment, a precursor of the near-infrared luminescent lanthanide ion is preferably one or more selected from Yb (ytterbium), Nd (neodymium), Er (erbium), Ho (holmium), Tm (thulium), and derivatives containing same.

According to an embodiment, the lanthanide ion precursor preferably contains an element having an emission wavelength in the visible light wavelength region.

According to an embodiment, the lanthanide ion or the derivative containing same is preferably included in an amount of 0.001 to 10 parts by weight on the basis of 100 parts by weight of the aluminum hydroxide precursor.

According to an embodiment, the solar wavelength conversion material preferably further comprises an aromatic ring compound or a derivative thereof.

According to an embodiment, the aromatic ring compound or the derivative thereof is preferably located within 10 nm from the aluminum hydroxide precursor or aluminum hydroxide derived therefrom, or is preferably formed by a covalent bond.

According to an embodiment, the aromatic ring compound is preferably one or more of an aromatic hydrocarbon in which only carbons and hydrogens are bonded together, an aromatic heterocyclic compound in which some of the carbon atoms forming a ring are substituted with oxygen, nitrogen, or sulfur atoms, other than carbon, or a derivative in which some of hydrogens are substituted with functional groups in the aromatic hydrocarbon and aromatic heterocyclic compound molecules.

According to an embodiment, the aromatic ring compound is preferably one or more of furan, benzbenzofuran, isobenzbenzofuran, pyrrole, indole, isoindole, thiophene, benzbenzothiophene, imidazole, benzimidazole, purine, pyrazole, indazole, oxazole, benzoxazole, oxazole isoxazole, benzoxazole isoxazole, thiazole, benzbenzothiazole, benzbenzene, naphthalene, anthracene, pyridine, quinoxaline, acridine, pyrimidine, quinazoline, pyridazine, cinnoline, phthalazine, 1,2,3-triazine, 1,2,4-triazine, 1,3,5-triazine and derivatives thereof.

According to an embodiment, the particle size of the solar wavelength conversion material is preferably in the range of 0.5 nm to 500 μm.

According to an embodiment, the maximum absorption wavelength of the solar wavelength conversion material is 200 nm to 500 nm, preferably 300 to 450 nm.

According to an embodiment, the maximum emission wavelength of the solar wavelength conversion material is preferably 450 nm to 1100 nm.

To achieve another objective of the present invention, the present invention provides a solar cell encapsulant comprising the solar wavelength conversion material according to the present invention.

According to an embodiment, the encapsulant is preferably in the form of a film having a thickness of 100 μm or less.

According to an embodiment, the encapsulant is preferably EVA (ethylene vinyl acetate), POE (polyolefin elastomer), cross-linked polyolefin (PO), TPU (thermal polyurethane), PVB (polyvinyl butyral), silicone, silicone/polyurethane hybrid, or ionomer.

According to an embodiment, the solar wavelength conversion material is preferably contained in an amount of 0.0001 to 10 parts by weight, preferably 1 to 10 parts by weight, on the basis of 100 parts by weight of the resin of the encapsulant.

To achieve another objective of the present invention, the present invention provides a solar cell comprising the solar wavelength conversion material or the solar cell encapsulant, according to the present invention.

According to an embodiment, the solar wavelength conversion material is preferably coated on the front surface of the solar cell or on the back surface of the encapsulant on the front surface of the solar cell.

According to an embodiment, the coating is preferably spray coating or screen coating.

According to an embodiment, the solar cell encapsulant is preferably EVA (ethylene vinyl acetate), POE (polyolefin elastomer), cross-linked polyolefin (PO), TPU (thermal polyurethane), PVB (polyvinyl butyral), silicone, silicone/polyurethane hybrid, or ionomer.

In addition, in a preferred embodiment of the present invention, the encapsulant according to the present invention is laminated on the front and rear surfaces of the solar cell, glass is laminated on the front surface of the encapsulant located on the front surface of the solar cell, and a back sheet is laminated on the back surface of the encapsulant located on the back surface of the solar cell.

### Advantageous Effects of Disclosure

When a solar module is manufactured by uniformly dispersing a solar wavelength conversion material having ultraviolet absorption and visible photoluminescence characteristics in a resin, not only ultraviolet blocking effect by ultraviolet absorption but also a down-conversion effect of visible photoluminescence can be expected, thereby manufacturing a solar module with an increased output along with durability.

In addition, the durability of an encapsulant can be further improved by the heat-resistant, moisture-resistant effects due to aluminum hydroxide materials capable of absorbing heat and moisture.

Therefore, a solar module including an encapsulant in which a solar wavelength conversion material having such a photoluminescence characteristic is dispersed can prevent a decrease in output due to long-term outdoor exposure by increasing long-term durability, which assists in solar energy generation.

In addition, the solar wavelength conversion material according to the present invention can emit one or more photons from ultraviolet light having low photocurrent conversion efficiency of a solar cell to visible and near-infrared light wavelength regions having high photocurrent conversion efficiency, thereby maximizing the efficiency of a solar cell.

Moreover, the solar wavelength conversion material according to the present invention introduces an aromatic ring compound and/or a lanthanide ion in the step for synthesizing luminescent aluminum hydroxide to further increase absorbance in the ultraviolet region, thereby enabling effective down-conversion, and at the same time to improve the durability of the solar cell, thereby lowering the power generation cost of the solar cell and ensuring long-term output.

When the solar wavelength conversion material is coated on the front side of the solar cell or the back side of the encapsulant on the front side of the solar cell, the efficiency of the solar cell can be increased. When the material is directly coated on the solar cell, down-conversion is induced, thereby improving the output.

In addition, when the solar wavelength conversion material is located at the interface between the encapsulant and the solar cell, the increased photovoltaic current due to an anti-reflective coating effect, and the anti-PID (potential induced degradation) effect of a solar energy module due to trapping of Na+ ions generated from the tempered glass of the module, and the anti-LeTID (light and elevated temperature induced degradation) effect due to UV blocking and heat dissipation properties, can also be expected.

### BRIEF DESCRIPTION OF DRAWINGS

FIG. 1 is a cross-sectional schematic view of an encapsulant in which luminescent aluminum hydroxide particles are dispersed, a solar photovoltaic (PV) cell including same, and a solar module.

FIG. 2 is a schematic diagram showing the principle of aluminum hydroxide photoluminescence for ultraviolet absorption and visible and near-infrared photoluminescence: (a) visible photoluminescence principle; and (b) visible and near-infrared photoluminescence principles.

FIG. 3 shows absorbance and photoluminescence spectrums of luminescent aluminum hydroxide: dotted line representing absorbance; and solid line representing photoluminescence spectrum.

FIG. 4 shows excitation and photoluminescence spectrums of near-infrared luminescent aluminum hydroxide: (a) Yb doping; (b) Ce, Yb doping; (c) Tb, Yb doping; and (d) Yb, 2-naphthoic acid doping.

FIG. 5 shows a spectrum showing a change in the photoluminescence (PL) intensity according to 2-naphthoic acid doping of near-infrared luminescent aluminum hydroxide.

FIG. 6 shows extinction and photoluminescence spectrums of luminescent aluminum hydroxide containing luminescent aluminum hydroxide, an aromatic ring compound and derivatives thereof:

(a) and (d) show extinction and photoluminescence spectrums of luminescent aluminum hydroxide (AlOH);

(b) and (e) show extinction and photoluminescence spectrums of luminescent aluminum hydroxide containing 2-napthoic acid containing (AlOH-NA); and

(c) and (f) show extinction and photoluminescence spectrums of luminescent aluminum hydroxide containing 1,2,3,4-tetrahydrocarbazole-4-one (AlOH-CA).

FIG. 7 shows time-resolved fluorescence spectrums of luminescent aluminum hydroxides of (a) AlOH and (b) AlOH-NA.

FIG. 8 shows total transmittance spectrums of a solar encapsulant before and after introduction of luminescent aluminum hydroxides and UV absorbers: dash-double dotted line represents total transmittance of EVA, dash-single dotted line represents total transmittance of EVA-AlOH 0.1, solid line represents total transmittance of EVA-AlOH 0.5, and dotted line represents total transmittance of EVA-C81 0.2).

FIG. 9 shows total transmittance spectrums of encapsulants before and after the introduction of luminescent aluminum hydroxides: (a) UV aging after 2000 hours; and (b) damp-heat aging after 2000 hours.

FIG. 10 shows external quantum efficiency spectrums of a solar cell #2 of Tables 5 and 6 and a cell coated with AlOH-NA-Yb of Example 4.

FIG. 11 shows spectrums obtained by measuring changes in the total reflectance of a solar cell #2 of Tables 5 and 6 and a cell coated with AlOH-NA-Yb of Example 4;

FIG. 12 shows external quantum efficiency spectrums before and after coating a silicon solar cell with luminescent aluminum hydroxide.

FIG. 13 shows reflectance spectrums before and after coating a silicon solar cell with luminescent aluminum hydroxide.

### BEST MODE

Hereinafter, the present invention will be described in more detail, but this is for more specifically explaining the present invention and is not intended to limit the scope of the present invention.

According to an embodiment of the present invention, the present invention provides a solar wavelength conversion material comprising luminescent aluminum hydroxide having ultraviolet absorption and visible photoluminescence characteristics.

Solar wavelength conversion materials are largely divided into two types: down-conversion and up-conversion depending on the photo-conversion method.

First, down-conversion is divided into down-shifting in which one photon of a short wavelength (e.g., ultraviolet) having higher energy than the silicon bandgap is absorbed and then converted into a photon in the long wavelength region having lower energy that silicon can absorb well; and quantum-cutting in which an absorbed photon is converted into two or more photons in a low energy region of a wavelength that is twice as long as the absorbed wavelength.

Conversely, a technology in which two photons in the infrared region having smaller energy than the band gap of silicon are absorbed and transmitted without being absorbed by silicon to then be converted into one photon in the high visible light region, which can be easily absorbed by silicon, is called up-conversion.

According to an embodiment of the present invention, provided is a solar wavelength conversion material comprising: a luminescent aluminum hydroxide precursor; and a lanthanide ion or a derivative containing same.

According to an embodiment of the present invention, provided is a solar wavelength conversion material comprising: a luminescent aluminum hydroxide precursor; and an aromatic ring compound or a derivative thereof.

The present invention relates to a solar wavelength conversion material with improved efficiency, containing low-cost luminescent aluminum hydroxide and a solar cell comprising same, and concerns a technology for improving photocurrent conversion efficiency according to an increase in short-circuit current by inducing down-conversion, anti-reflective coating effect, and durability improvement by locating the solar wavelength conversion material at the interface of the solar cell and the front encapsulant into which sunlight is incident, or by dispersing same in the encapsulant.

FIG. 1 is a cross-sectional schematic view of an encapsulant in which luminescent aluminum hydroxide particles are dispersed, a solar photovoltaic (PV) cell including same, and a solar module.

Referring to FIG. 1, a silicon solar cell module may be manufactured through lamination after stacking glass/encapsulant layer/solar photovoltaic (PV) cell/encapsulant layer/back sheet in that order from the front side where light is incident.

<Solar Wavelength Conversion Material>

In order to manufacture a solar wavelength conversion material that is capable of improving the photocurrent conversion efficiency and improving the durability of an encapsulant, luminescent aluminum hydroxide which is a low-cost material and have characteristics such as excellent absorbance and photoluminescence characteristics, heat resistance, and moisture resistance is used in the present invention.

The luminescent aluminum hydroxide includes an Al(OH)₃, AlOOH, 5Al₂O₃.2H₂O, or Al₂O₃ structure, and in the present invention, this structure is hereinafter referred to as aluminum hydroxide, AlOH or aluminum hydroxide.

The luminescent aluminum hydroxide precursor is one of aluminum monoacetate, aluminum triacetate, aluminum diacetate, triethyl aluminum, trimethyl aluminum, aluminum alkoxide, diethyl aluminum chloride, aluminum sulfate, aluminum cyanide, aluminum nitrite, aluminum carbonate, aluminum sulfite, aluminum hydroxide, aluminum oxide, aluminum chlorate, aluminum sulfide, aluminum chromate, aluminum trichloride, aluminum perchlorate, aluminum nitrate, aluminum permanganate, aluminum hydrogen carbonate, aluminum phosphate, aluminum oxalate, aluminum hydrogen phosphate, aluminum thiosulfate, aluminum chlorite, aluminum hydrogen sulfate, aluminum dichromate, aluminum bromide, aluminum hypochlorite, aluminum chloride hexahydrate, aluminum dihydrogen phosphate, aluminum phosphite, aluminum potassium sulfate dodeca hydrate, aluminum bromate, aluminum nitride, or derivatives thereof.

According to an embodiment, the luminescent aluminum hydroxide preferably has a porous structure. The prepared luminescent aluminum hydroxide can be synthesized to have porosity depending on variables such as precursors, solvents, impurities, or thermal decomposition reaction temperature and time, and when the prepared luminescent aluminum hydroxide has a porosity, the surface area thereof increases, and thus durability such as moisture resistance and heat resistance of the encapsulant may be improved.

According to an embodiment of the present invention, the solar wavelength conversion material according to the present invention preferably further contains a lanthanide ion or a derivative containing same.

Specifically, if a lanthanide ion enabling near-infrared photoluminescence is introduced, ultraviolet light can be absorbed and visible light and near-infrared light can be simultaneously emitted, and thus a higher photocurrent conversion rate can be realized when applied to a high-efficiency solar cell with excellent power generation efficiency in the visible and near-infrared wavelength range.

In addition, when aluminum hydroxide absorbs high energy in the ultraviolet light wavelength region and transfers same to the lanthanide ion enabling near-infrared photoluminescence, two photons are emitted in the near-infrared light wavelength region having low energy of a long wavelength that is more than twice the absorption wavelength, thereby maximizing the photocurrent conversion rate of a solar cell.

The lanthanide ion may emit light in near-infrared, ultraviolet, or visible light wavelength regions.

According to an embodiment of the present invention, in order to induce near-infrared photoluminescence, some lanthanide ions may be introduced. The near-infrared luminescent lanthanide precursor capable of emitting light in the near-infrared region with a long wavelength of 800 nm or more may include Yb (ytterbium), Nd (neodymium), Er (erbium), Ho (holmium), Tm (thulium), etc., and according to the external quantum efficiency characteristics of a solar cell, ions having a photoluminescence spectrum at a wavelength having a high photocurrent conversion efficiency of the solar cell may be selected and doped into aluminum hydroxide.

According to an embodiment of the present invention, a lanthanide ion enabling near-infrared photoluminescence is selected, and for example, when Yb is selected, all derivatives including Yb may be used as a precursor of Yb. Examples thereof may include ytterbium trifluoromethanesulfonate, ytterbium trifluoromethanesulfonate hydrate, ytterbium chloride, ytterbium fluoride, ytterbium iodide, ytterbium chloride hydrate hexahydrate, ytterbium oxide, ytterbium nitrate pentahydrate, ytterbium acetate hydratecetrahydrate, ytterbium acetate hydrate, ytterbium polystyrenesulfonate, 3-hydroxy-2-naphthoic (2-hydroxyl benzylidene) hydrazide, ytterbium isopropoxide, ytterbium bromide, tris[N,N-bis(trimethylsilyl)amide]ytterbium, and so on.

According to an embodiment of the present invention, in addition, in order to induce effective energy transfer from luminescent aluminum hydroxide to near-infrared light, a lanthanide-based ion precursor including Ce, Tb, Eu, etc. having a photoluminescence wavelength in the visible light wavelength region may be doped together.

According to an embodiment of the present invention, the lanthanide ion or the derivative comprising same may be included in an amount of 0.001 to 10 parts by weight on the basis of 100 parts by weight of the aluminum hydroxide precursor. When the lanthanide ion is introduced in excess outside the range of 0.001 to 10 parts by weight on the basis of 100 parts by weight of the aluminum hydroxide precursor, the photoluminescence performance may be deteriorated by quenching due to aggregation of lanthanide ions, and when a small amount of the lanthanide ion or the derivative comprising same is introduced, energy transfer from the luminescent aluminum hydroxide to the lanthanide ion may be limited, and thus a down-conversion effect may be difficult to expect.

According to an embodiment of the present invention, when an impurity or aromatic ring compound and a derivative thereof are appropriately added, the trap state of aluminum hydroxide may be changed, and the position of the emission wavelength may also be controlled depending on the changed trap state.

According to an embodiment of the present invention, the aromatic ring compound or a derivative containing same may be included in an amount of 0.001 to 10 parts by weight on the basis of 100 parts by weight of the aluminum hydroxide precursor.

In addition, when the light absorbed by the aromatic ring compound and the derivative thereof is located at higher energy than trap emission, energy transfer is achieved from the aromatic ring compound and the derivative thereof to the trap state of aluminum hydroxide. In this case, the photoluminescence intensity of the near-infrared luminescent aluminum hydroxide is amplified by additional energy transfer. That is, the aromatic ring compound and the derivative thereof may act as an antenna that captures light in the ultraviolet light wavelength region and transmits the captured light to aluminum hydroxide.

Therefore, in the case where the aromatic ring compound and the derivative thereof exist together than in the case where aluminum hydroxide exists alone, effective ultraviolet absorption and stronger visible and near-infrared photoluminescence can be realized. In addition, since the position of the trap state is lowered, the emission wavelength moves to a longer wavelength, and the Stokes shift, which is a difference between the absorption wavelength and the emission wavelength, may increase, thereby reducing reabsorption of the light emitted from a material.

For effective energy transfer from the aromatic ring compound and the derivative thereof to aluminum hydroxide, the distance between the two materials must be located within 10 nm or form a covalent bond. Therefore, the aromatic ring compound is preferably located within 10 nm from the aluminum hydroxide precursor or aluminum hydroxide derived therefrom, or in a state formed by a covalent bond.

According to an embodiment of the present invention, the aromatic ring compound is preferably one or more of an aromatic hydrocarbon in which only carbons and hydrogens are bonded together, an aromatic heterocyclic compound in which some of the carbon atoms forming a ring are substituted with oxygen, nitrogen, or sulfur atoms, other than carbon, or a derivative in which some of hydrogens are substituted with functional groups in the aromatic hydrocarbon and aromatic heterocyclic compound molecules.

According to an embodiment of the present invention, the aromatic ring compound may be selected from one or more of furan, benzbenzofuran, isobenzbenzofuran, pyrrole, indole, isoindole, thiophene, benzbenzothiophene, imidazole, benzimidazole, purine, pyrazole, indazole, oxazole, benz oxazolebenzoxazole, oxazoleisoxazole, benzoxazoleisoxazole, thiazole, benzbenzothiazole, benzbenzene, naphthalene, anthracene, pyridine, quinoxaline, acridine, pyrimidine, quinazoline, pyridazine, cinnoline, phthalazine, 1,2,3-triazine, 1,2,4-triazine, 1,3,5-triazine, and derivatives thereof.

The solar wavelength conversion material may be prepared by using a hydrothermal, sol-gel, thermal decomposition synthesis method, or the like. In the present invention, the present invention will be described in more detail through a pyrolytic synthesis method, but the scope of the present invention is not limited thereto.

In the case of synthesizing luminescent aluminum hydroxide by the thermal decomposition synthesis method, a material having a boiling point higher than the thermal decomposition temperature of the aluminum precursor may be used as a solvent. For example, a material having a high boiling point of 200° C. or higher, such as hexadecylamine, 1-eicosene, 1-octadecene, docosane, phenyl ether, benzyl ether, octyl ether, oleic acid, oleylamine, polyisobutylene, etc. is used as a solvent.

The solvent may act as a solvent and provide impurities such as carbon, carbonyl radical, oxalic phosphoric radical, sulfuric acid, etc., and thus may control photoluminescence characteristics or may function to further improve luminous performance. In addition, in the pyrolysis synthesis step, by adding impurities, such as alkyl (C₁ to Cₙ) acetate, and thus the absorbance and photoluminescence characteristics can be controlled.

In addition, absorption of light in the pyrolysis synthesis step, specifically absorbance of near-infrared luminescent aluminum hydroxide when an aromatic ring compound having a high extinction coefficient in the ultraviolet light wavelength region, and a derivative thereof, are appropriately added, increased photoluminescence, large Stoke's shift, etc. can be induced. Therefore, in the pyrolytic synthesis step, the aromatic ring compound is added together with the aluminum hydroxide precursors and lanthanide ions.

One or more of the aluminum precursors, one or more of the lanthanide ions, and one of the aromatic ring compound and the derivative thereof are dispersed in the solvent and then reacted at the pyrolysis temperature of the aluminum precursor. When the reaction is completed, the product can be isolated and purified to obtain a final luminescent aluminum hydroxide (solar conversion material).

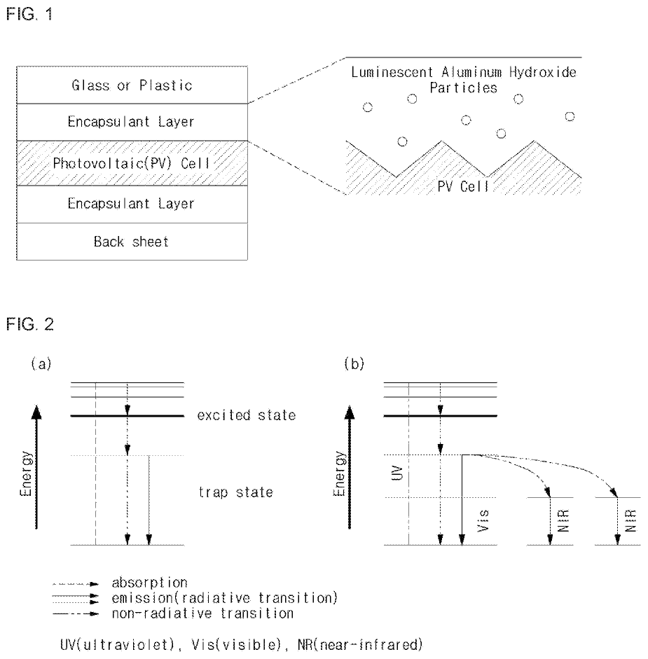

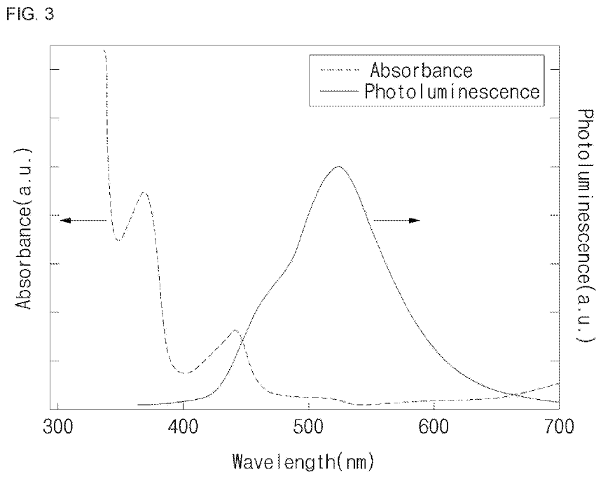

The reason why the aluminum hydroxide produced by pyrolysis synthesis exhibits photoluminescence characteristics is trap emission from defects in the metal oxide. In trap emission, a trap state that is another energy level is formed between the ground state and the excited state when defects exist in the material, and electrons transferred from the ground state to the excited state by external energy are stabilized and moved to a lower energy level generated due to defects, and emit light while making transition to the final ground state (FIG. 2(a)). In this case, when a small amount of one or more of the lanthanide ions enabling near-infrared photoluminescence is doped, energy transfer occurs from aluminum hydroxide to the lanthanide-based ion, and near-infrared photoluminescence appears at low energy with a wavelength more than twice the photoluminescence wavelength of aluminum hydroxide. Specifically, two or more photons may be emitted in the near-infrared light wavelength region (FIG. 2(b)).

Since the solar wavelength conversion material is located at the front part of a solar cell, particles that are smaller in size than the wavelength of sunlight incident on the solar cell are advantageously used. If the particle size is similar to or larger than the wavelength of the incident sunlight, the incident sunlight may be scattered or reflected, and thus the efficiency of the entire solar cell may be reduced. Accordingly, the particle size of the solar wavelength conversion material may be in the range of 0.5 nm to 500 μm, preferably 1 nm to 100 μm or less.

The luminescent aluminum hydroxide according to the present invention preferably has an absolute quantum yield of 40% or more.

FIG. 3 shows absorbance and photoluminescence spectrums of luminescent aluminum hydroxide prepared by a pyrolysis synthesis process. More specifically, the dotted line represents the absorbance spectrum of aluminum hydroxide, which starts absorbance at 450 nm and shows strong absorbance in the ultraviolet region, and the solid line represents the photoluminescence spectrum, showing the maximum emission peak at 526 nm.

In order to apply the solar wavelength conversion material to a silicon solar cell, the solar wavelength conversion material should have absorbance in the ultraviolet light wavelength region and have photoluminescence characteristics in the visible and near-infrared light wavelength regions. Specifically, the absorbance wavelength region of the solar wavelength conversion material is preferably formed in 200 to 500 nm. In addition, the photoluminescence wavelength region is preferably formed at 450 nm or more, preferably 450 nm to 1100 nm.

Specifically, with regard to the solar wavelength conversion material, it is preferable that the absorbance wavelength and the photoluminescence wavelength region do not overlap, and a material having a large Stokes shift is advantageously used because when the absorbance wavelength and the photoluminescence wavelength region overlap, reabsorption in which the light emitted from the material is absorbed again, may act as a loss.

The prepared luminescent aluminum hydroxide can be synthesized to have porosity depending on variables such as precursors, solvents, impurities, or thermal decomposition reaction temperature and time, and when the luminescent aluminum hydroxide has porosity, the surface area increases, the durability of the solar module, such as moisture resistance and heat resistance, can be improved.

The characteristics required for a solar wavelength conversion material, specifically a down-conversion material, include high luminous efficiency, a high extinction coefficient, high light safety, UV absorbance, photoluminescence below visible light wavelength and a large Stoke's shift (a wavelength difference between the maximum absorbance wavelength and the maximum photoluminescence wavelength (Δλ=λₑₘ−λ_{ab})), etc.

In order to apply the down-conversion material to a solar cell, the required characteristics must be appropriately met. Otherwise, the efficiency of the solar cell may be reduced. For example, when a low luminous efficiency material is introduced into the front part of a solar cell, sunlight may be absorbed but may not be converted into visible light, and thus solar absorbance of the solar cell may be rather hindered.

In addition, a material having a low extinction coefficient is difficult to expect a down-conversion effect because the absorbance efficiency of the material is low even if the luminous efficiency is high. For materials with absorbance in the visible light wavelength region lower than the ultraviolet light wavelength region, commercially available silicon solar cells cannot expect an additional down-conversion effect because the photocurrent conversion efficiency is already as high as 90% in the visible light wavelength region. Moreover, a material having a small Stoke's shift has a large degree of overlapping between the absorption wavelength and the photoluminescence wavelength, and thus there may be a loss due to reabsorption of the light emitted, making it difficult to expect effective down-conversion.

Meanwhile, when quantum-cutting is induced, photons having short wavelengths, which cannot be absorbed by a solar cell, are emitted as two or more photons having long wavelengths in which the conversion efficiency of a solar cell is high, thereby dramatically improving the efficiency of the solar cell.

According to an embodiment, the solar wavelength conversion material is preferably used in the form of a film having a thickness of 100 μm or less prepared by being dispersed in a light-transmitting resin.

Hereinafter, in order to prove that the solar wavelength conversion material manufactured according to the present invention is an excellent solar wavelength conversion material capable of improving the efficiency of a solar cell, the present invention will be described with reference to the drawings.

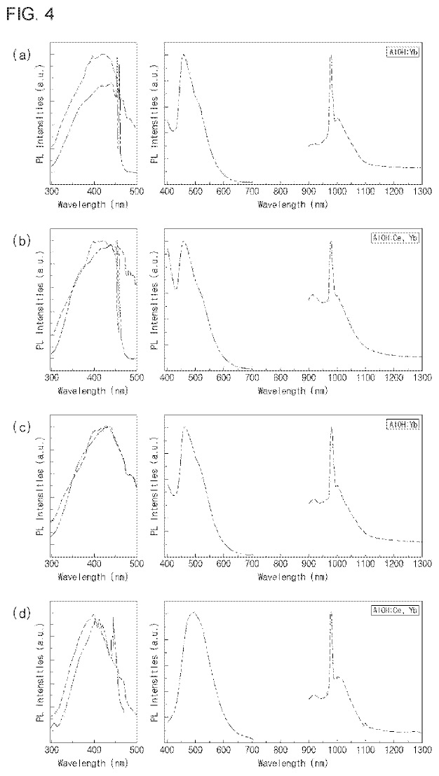

FIG. 4 shows excitation and photoluminescence spectrums of the thus prepared near-infrared luminescent aluminum hydroxide. FIG. 4(a) shows excitation and photoluminescence spectrums of the near-infrared luminescent aluminum hydroxide doped with Yb alone. When ultraviolet light of 350 nm is irradiated by using a Xe lamp as an excitation light source, blue light emission near 450 nm (dashed dotted line) and near infrared light emission near 1000 nm (dotted line) appear simultaneously. In order to determine in which wavelength region the visible light and near-infrared photoluminescence from aluminum hydroxide was absorbed and expressed, the excitation spectrum was analyzed.

In FIG. 4(a), the dashed-dotted line represents an excitation spectrum of 450 nm photoluminescence, and the dotted line represents an excitation spectrum of 1000 nm photoluminescence. That is, it was confirmed that both visible photoluminescence and near-infrared photoluminescence appeared by absorbing a wavelength in the ultraviolet region in the range of 300 nm to 500 nm. In addition, in FIGS. 4(b) and 4(c), even when Ce and Tb are additionally introduced, Ce and Tb photoluminescence peaks are not observed, but only aluminum oxide and Yb photoluminescence peak are observed, confirming that effective energy transfer occurs in the order of aluminum hydroxide, Ce (or Tb), and Yb.

Meanwhile, FIG. 4(d) shows the excitation and photoluminescence spectrums of near-infrared luminescent aluminum hydroxide prepared by introducing 2-naphthoic acid together with Yb as one of the aromatic ring compounds and a derivative thereof. In FIG. 4(d), the dash-double dotted line and the dotted line indicate the maximum emission peaks in the vicinity of 500 nm, 1000 nm, respectively, in the photoluminescence spectrum. When 2-naphthoic acid is added, it can be seen that the maximum emission peak shifts to a longer wavelength of about 50 nm compared to FIG. 4(a), which means that the trap state is changed, as described above, by the introduction of 2-naphthoic acid, and also means that the reabsorption loss is reduced due to the long wavelength shift of the photoluminescence spectrum. In addition, since the emission peak of Yb was observed in the near-infrared wavelength region, it was confirmed that effective energy transfer was realized in the order of 2-naphthoic acid, aluminum hydroxide, and Yb. As described with reference to FIGS. 4(a) to 4(c), it was confirmed through the observation of the excitation spectrum that visible light and near-infrared light emitted around 500 nm and 1000 nm were all absorbed by the wavelength of the ultraviolet region in the range of 300 nm to 500 nm (FIG. 4(d)).

FIG. 5 shows the photoluminescence spectrum of near-infrared luminescent aluminum hydroxide with Yb alone or Yb added with 2-naphthoic acid. The dotted line represents the photoluminescence spectrum in which only Yb is doped, and the solid line represents the photoluminescence spectrum in which Yb and 2-naphthoic acid are introduced together. It was confirmed that when 2-naphthoic acid was added, the photoluminescence amplification of aluminum hydroxide and effective energy transfer to Yb were achieved as the ultraviolet absorption increased, and thus the photoluminescence intensity of Yb was increased.

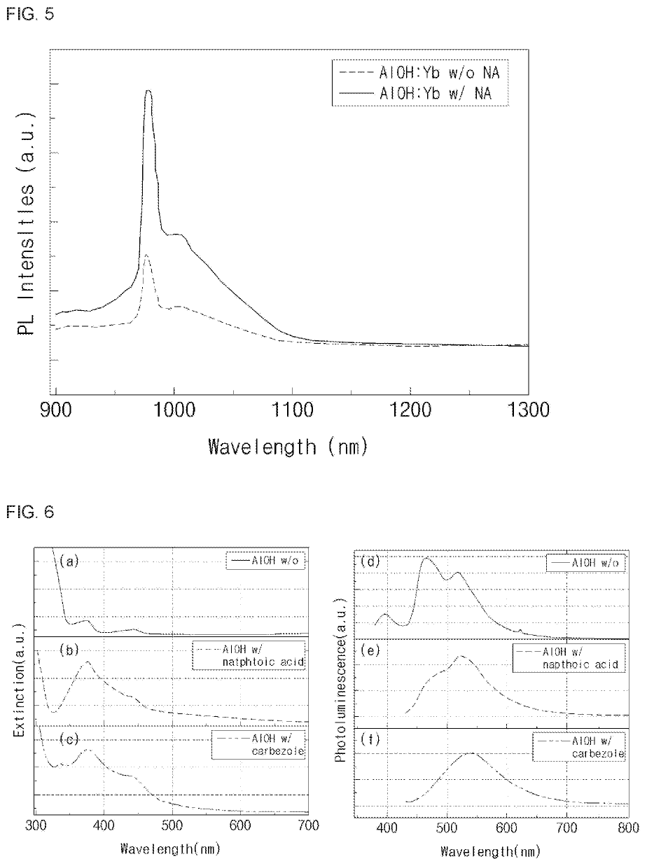

FIG. 6 shows extinction and photoluminescence spectrums of luminescent aluminum hydroxide complexes. Specifically, FIGS. 6(a) and 6(d) show extinction and photoluminescence spectrums of aluminum hydroxide alone (AlOH), respectively, in which absorption starts at 450 nm and the absorption is exhibited in the ultraviolet region. In addition, photoluminescence characteristic peaks are shown at 390 nm, 465 nm, and 514 nm, and the maximum emission wavelength is 465 nm. FIGS. 6(b) and 6(e) show extinction and photoluminescence spectrums of luminescent aluminum hydroxide (AlOH-NA) prepared by introducing 2-naphthoic acid together with an aluminum precursor in the synthesis step. Similar to the case of aluminum hydroxide alone AlOH, absorption starts at 450 nm and strong absorption is exhibited in the wavelength region of 380 nm. Meanwhile, the maximum emission wavelength was 520 nm, which was shifted to a longer wavelength of about 55 nm compared to AlOH. FIGS. 6(c) and 6(f) show extinction and photoluminescence spectrums of luminescent aluminum hydroxide (AlOH-CA) prepared by introducing 1,2,3,4-tetrahydrocarbazole-4-one together with an aluminum precursor in the synthesis step, in which absorption starts at 450 nm and strong absorption is exhibited in the wavelength region of 370 nm. Meanwhile, the maximum emission wavelength was 530 nm, which was shifted to a longer wavelength of about 65 nm compared to AlOH. As confirmed from the results of FIG. 6, when the aromatic ring compound is introduced in the pyrolysis synthesis step, the absorption in the ultraviolet region is improved, and a difference between the maximum absorption wavelength and the photoluminescence wavelength is further increased, thereby minimizing a loss due to reabsorption.

The change in the photoluminescence characteristics of luminescent aluminum hydroxide by the addition of the aromatic ring compound and the derivative thereof and the energy transfer effect by the aromatic ring compound and the derivative thereof can be more clearly understood through time-resolved fluorescence (TRF).

FIGS. 7(a) and 7(b) show TRF spectrums of AlOH and AlOH-NA, and an average lifetime (Tₐᵥₑ) can be calculated from these spectrums. FIG. 7(a) shows AlOH emission wavelengths observed at 400 nm, 450 nm, and 500 nm, respectively, and the average lifetime (Tₐᵥₑ) values were 1.07 ns, 2.19 ns, and 3.39 ns, respectively. Meanwhile, FIG. 7(b) shows that the emission wavelengths of AlOH-NA were observed at 400 nm, 450 nm, 500 nm, and 520 nm, respectively, and it can be seen that the average lifetime of AlOH-NA for each wavelength is larger than that of AlOH, and the average lifetime (Tₐᵥₑ) values calculated on the basis of this graph were 1.21 ns, 8.18 ns, 11.25 ns, and 11.84 ns, respectively. This means that the average lifetime according to the emission of AlOH was generally delayed due to energy transfer of ultraviolet light absorbed by NA to AlOH. That is, when the aromatic ring compound or derivative thereof is introduced together in the synthesis step, it can be seen that strong absorption of light in the ultraviolet region and effective energy transfer are realized. This means that effective down-conversion is achieved.

Methods for introducing the synthesized solar wavelength conversion material into a solar cell may include, according to the location where the material is introduced, a method for manufacturing a silicon solar cell in the form of a sheet by dispersing the material in an encapsulant serving to protect the silicon solar cell, a method for directly applying the material on the entire surface of the silicon solar cell, a method for applying the material to the surface of an encapsulant bonded to the front surface of the solar cell, and so on.

<Solar Cell Encapsulant>

The solar wavelength conversion material is dispersed in a resin to form a sheet and used in the manufacture of a solar photovoltaic module.

First, as the encapsulant of a solar cell, a material such as ethylene vinyl acetate (EVA), polyolefin elastomer (POE), cross-linked polyolefin, thermal polyurethane (TPU), polyvinyl butyral (PVB), silicone, silicone/polyurethane hybrid, ionomer, etc. are used, and EVA or POE is most frequently used.

In general, a number of methods for manufacturing a solar cell module through thermal lamination after introducing a solar wavelength conversion material into an encapsulant and placing same on the front surface of the solar cell are being reported, and there are cases where the reported methods are applied to commercial production.

However, in this case, due to a large difference between the refractive index (n˜1.4) of a polymer such as EVA or POE constituting the encapsulant and the refractive index (n˜2.5) of SiNx on the surface of the silicon solar cell, the light emitted from the solar wavelength conversion material inside the encapsulant does not travel to the solar cell but travels toward the side of an encapsulant sheet because the waveguide phenomenon due to total internal reflection inside the encapsulant predominates. This phenomenon may act as a light loss from the solar cell side.

<Applying to Surface of Solar Cell>

Conversely, when applied to the surface of a solar cell or the surface of an encapsulant, the solar wavelength conversion material is located at the interface between the encapsulant and the solar cell, and due to the silicon texturing structure of several microns (μm) to several tens of microns (μm), the light cannot travel laterally but travels toward the inside of the solar cell. In addition, if the solar wavelength conversion material can be adjusted to have a value between the encapsulant refractive index (n˜1.4) and the solar-cell-surface refractive index (n˜2.5), the entry of light toward the encapsulant, the solar wavelength conversion material and the solar cell may become very advantageous according to the Snell's law, and thus the light can be more utilized from the solar cell side, thereby improving the photocurrent conversion efficiency. That is, both the down-conversion effect of the solar wavelength conversion material and the anti-reflective coating effect can be expected.

When dispersed in a solvent, the solar wavelength conversion material can be applied on the surface of a solar cell. The methods for applying the solar cell surface may include spin coating, bar coating, spray coating, dip coating, screen printing, and the like. In addition, when applied to the encapsulant, all of the methods, except for spin coating, can be applied.

<Solar Cell Module/Solar Cell>

According to an embodiment of the present invention, in the case of a silicon solar module, as shown in the schematic diagram of FIG. 1, glass/encapsulant layer/photovoltaic (PV) cell/encapsulant layer/back sheet) are stacked in that order from the front surface where light is incident, and the silicon solar cell module may then be manufactured through lamination, wherein the luminescent aluminum hydroxide may be dispersed in the front-surface encapsulant or in both of the front-and-back surface encapsulants.

According to an embodiment of the present invention, the type and size of the material constituting the solar cell is not limited thereto. For example, the present invention relates to a solar cell which can be applied irrespective of the type of material, including an organic photovoltaic cell (OPV), a solar cell based on a semiconductor such as copper indium gallium selenide (CIGS), cadmium telluride (CdTe), perovskite, etc., a silicon-based solar cell, and a semiconductor-silicon tandem structure-based solar cell, wherein the photocurrent conversion efficiency of the solar cell is improved.

However, for explanation of the invention, a 6-inch polycrystalline silicon solar cell was used and described.

In the present invention, a spray coating method by which fast and uniform coating is achieved in consideration of commercial production application is used, but is not limited thereto.

### MODE OF DISCLOSURE

Hereinafter, preferred embodiments of the present invention will be described in detail, but the following examples are only presented for a better understanding of the present invention, and the scope of the present invention is not limited to the following examples.

### Preparation Example 1: Preparation of Solar Wavelength Conversion Material (Aluminum Hydroxide Precursor)

10 g of aluminum acetate was mixed with 100 ml of 1-octadecene solvent, and then the thermal decomposition reaction was performed at 300° C. under stirring for 30 minutes. After completion of the reaction, aluminum hydroxide was separated by centrifugation and redispersed in 10 ml of toluene solvent. FIG. 3 shows the UV-Vis spectrum and photoluminescence spectrum of the thus-prepared luminescent aluminum hydroxide solution, in which the dotted line represents absorption, and the solid line represents photoluminescence spectrums. Examples based on the contents of aluminum hydroxide were set to Examples 1 and 2, respectively.

### Preparation Example 2: Preparation of Solar Wavelength Conversion Material (Aluminum Hydroxide Precursor+Lanthanide Ion)

10 g of aluminum acetate was mixed with 10 ml of 1-octadecene solvent. To this mixed solution, ytterbium (III) acetate hydrate among the near-infrared luminescent lanthanide ions presented above was added in an amount of 0.2 wt % compared to the aluminum precursor, and then thermal decomposition reaction was carried out at 300° C. under stirring for 30 minutes. After completion of the reaction, aluminum hydroxide was separated by centrifugation and redispersed in 10 ml of a toluene solvent. The thus synthesized solar wavelength conversion material was used in Example 3, and the solar wavelength conversion material synthesized without adding ytterbium (III) acetate hydrate was used in Comparative Example 5.

### Preparation Example 3: Preparation of Solar Wavelength Conversion Material (Aluminum Hydroxide+Aromatic Ring Compound)

10 g of aluminum acetate was mixed with 100 ml of 1-octadecene solvent, and then the thermal decomposition reaction was performed at 300° C. under stirring for 30 minutes. After completion of the reaction, aluminum hydroxide was separated by centrifugation and redispersed in 10 ml of toluene.

To control photoluminescence characteristics, 3-hydroxyl-2-naphthoic acid as an aromatic ring compound was added in an amount of 5 wt %, compared to aluminum acetate that is an aluminum precursor, and thermal decomposition reaction was carried out at 300° C. for 30 minutes under stirring, followed by separation and purification.

### Preparation Example 4: Preparation of Solar Wavelength Conversion Material (Aluminum Hydroxide+Lanthanide Ion+Aromatic Ring Compound)

A solar wavelength conversion material was prepared in the same manner as in Preparation Example 2, except that, in order to further strengthen UV absorbance and control the photoluminescence characteristics, 3-hydroxyl-2-naphthoic acid, which is one of the derivatives of aromatic ring compound, was added in an amount of 0.2 wt % compared to the aluminum precursor, and the thermal decomposition reaction was carried out in the same manner as above under stirring, followed by separation and purification. The thus-synthesized solar wavelength conversion material was used in Example 4, and a solar wavelength conversion material synthesized without adding without adding ytterbium (III) acetate hydrate was used in Comparative Example 6.

### Examples 1 and 2: Manufacture of Encapsulant Sheet Containing Solar Wavelength Conversion Material

The solar wavelength conversion material prepared in Preparation Example 1 was added to an encapsulant resin in an encapsulant sheet manufacturing step to then prepare an encapsulant sheet in which the solar wavelength conversion material was dispersed through extrusion. As the encapsulant resin, an ethylene vinyl acetate copolymer (manufactured by Hanwha Total Petrochemical Co., Ltd.) having a melt index of 15 g/10 min and a vinyl acetate content of 28 wt % was used. 1 part by weight of Luperox TBEC (tert-butyl-2-ethylhexyl monoperoxycarbonate) manufactured by Alkemas, 0.5 parts by weight of TAICROS (triallyl isocyanurate) manufactured by Evonik as a crosslinking aid, 0.1 parts by weight of Tinuvin 770 (bis-2,2,6,6,-tetramethyl-4-piperidinyl sebacate) manufactured by Ciba as a UV stabilizer, and 0.3 parts by weight of OFS-6030 (methacryloxypropyltrimethoxy siloxane) manufactured by Dow Corning as a silane coupling agent, were added to 100 parts by weight of EVA and mixed. Thereafter, EVA sheets was manufactured through an extruder, the extruder temperature was maintained at 100° C., the T-die temperature was maintained at 100° C., and the thicknesses of the prepared sheets were 0.5 mm. Hereinbelow, each of the thus prepared sheets will be denoted as “EVA”.

For comparative evaluation of durability, sheets were manufactured in the same manner as in the above-described EVA sheet manufacturing method, except that 0.1 or 0.5 parts by weight of luminescent aluminum hydroxide was additionally added to 100 parts by weight of EVA in the manufacturing method of the sheet EVA, and the manufactured sheets were denoted as “EVA-AlOH 0.1” and “EVA-AlOH 0.5”, and were set to Examples 1 and 2, respectively.

For comparative evaluation, a sheet which was manufactured in the same manner as in Example 1, except that luminescent aluminum hydroxide was not used (hereinafter to be referred to as “EVA” sheet), was used in Comparative Example 1, and the sheet was prepared in the same manner except that 0.1, 0.2, and 0.5 parts by weight of Chimassorb 81 (2-hydroxy-4-octyloxy-benzophenone) manufactured by Ciba were additionally added as a UV absorber, and were denoted as “EVA-C81 0.1”, “EVA-C81 0.2” and “EVA-C81 0.5”, respectively, which were used in Comparative Examples 2 to 4.

Examples and Comparative Examples are listed in Table 1 below according to the introduction of the luminescent aluminum hydroxide (AlOH) and the ultraviolet absorber (C81) and the contents thereof.

TABLE 1

| | Example | Example | Comparative | Comparative | Comparative | Comparative |
|---|---|---|---|---|---|---|
| | 1 | 2 | Example 1 | Example 2 | Example 3 | Example 4 |
| AIOH | 0.1 | 0.5 | — | — | — | — |
| added | | | | | | |
| (wt %) | | | | | | |
| C81 | — | — | — | 0.1 | 0.2 | 0.5 |
| added | | | | | | |
| (wt %) | | | | | | |

<Manufacture of Solar Module Comprising Encapsulant with Luminescent Aluminum Hydroxide Dispersed Therein>

Each of the encapsulant sheets manufactured in Examples 1 and 2 and Comparative Examples 1 to 4 was stacked in the order of glass (200 mm×200 mm), an encapsulant layer, a 6-inch polycrystalline solar cell manufactured by GINTECH, an encapsulant layer, and a back sheet based on PVDF(polyvinylidene fluoride) manufactured by SFC, and mini modules were manufactured through thermal lamination. In the thermal lamination process, after a vacuum step at 150° C. for 6 minutes, crosslinking was carried out by maintaining a difference between upper and lower pressures of a laminator at 0.4 MPa for 11 minutes.

### Experimental Example 1: Evaluation of Durability of Encapsulant

In order to evaluate the durability of the encapsulant according to the introduction of luminescent aluminum hydroxide, an accelerated weathering test was performed on a specimen in which the encapsulant was located between the manufactured mini solar module and two sheets of glass. For a UV aging experiment, by exposing the specimen to an ultraviolet lamp (340 nm, 0.9 W/m²) at a temperature of 63° C., the total transmittance characteristics (of glass specimens) and solar cell efficiency changes (of solar mini module specimens) over time were observed. For a damp-heat aging experiment, by exposing the specimen to conditions of a temperature of 85° C., and a humidity of 85%, the total transmittance characteristics (of glass specimens) and solar cell efficiency changes (of solar mini module specimens) over time were observed. A solar simulator (WXS-156S-10) manufactured by WACOM was used for analysis of solar cell efficiency, and an UltraScan PRO Spectrometer (HunterLab) was used for analysis of transmittance characteristics.

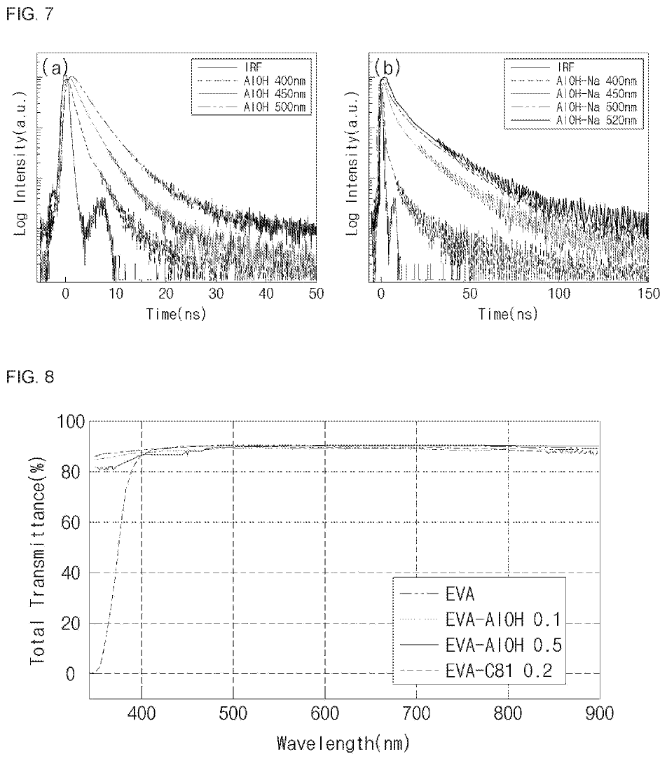

FIG. 8 shows the total transmittance of the specimens having undergone thermal lamination by placing the encapsulants of Examples 1 and 2 and Comparative Examples 1 and 3 between two glass substrates. The dash-double dotted line represents the total transmittance of an EVA specimen (Comparative Example 1), showing high transmittance of 90% in the entire wavelength region, EVA-AlOH 0.1 and EVA-AlOH 0.5 specimens (Examples 1 and 2) show absorption peaks by AlOH (aluminum hydroxide) in the ultraviolet region 450 nm or more and high transmittance of 90% in the visible region, which is similar to the EVA specimen (Comparative Example 1). Meanwhile, it can be seen that EVA-C81 (Comparative Example 3) has a sharp decrease in transmittance in the ultraviolet region of 400 nm or more. That is, as described above, when a UV absorber, is used, the durability of the encapsulant can be improved by a UV blocking effect. However, UV rays of 400 nm or less cannot be absorbed by a solar cell and cannot be converted into electricity, so that the initial output is undesirably decreased.

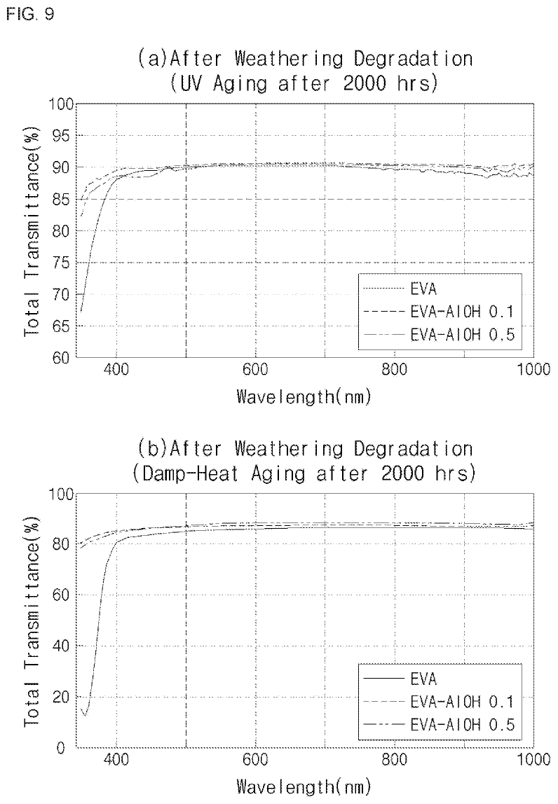

FIG. 9 shows the total transmittance of specimens having undergone thermal lamination by placing an encapsulant before and after introduction of luminescent aluminum hydroxide between two glass substrates after UV aging and damp-heat aging tests for 2000 hours. FIG. 9(a) shows results of UV aging test, and it was confirmed that the encapsulants of Example 1 (EVA-AlOH 0.1, dotted line) and Example 2 (EVA-AlOH 0.5, dash-double dotted line), in which aluminum hydroxide was introduced, maintained the same transmittance levels as before the accelerated test of FIG. 3, but EVA had decreased transmittance in the ultraviolet region of 400 nm or more. In addition, FIG. 9(b) shows results of damp-heat aging tests, and it was confirmed that the encapsulants of Example 1 (EVA-AlOH 0.1, dotted line) and Example 2 (EVA-AlOH 0.5, dash-double dotted line), in which aluminum hydroxide was introduced, maintained the same transmittance levels as before the accelerated test of FIG. 8, similarly to the UV aging test of FIG. 9(a), but EVA of Comparative Example 1 had sharply decreased transmittance in the ultraviolet region of 400 nm or more, which means that the light in the ultraviolet region of 400 nm or more cannot pass through the encapsulant and thus cannot reach the solar cell, suggesting that the solar cell cannot convert as much as the light into electricity.

Tables 2 to 4 show open-circuit voltage (V_{oc}), short-circuit current density (J_{sc}), fill factor (FF), and efficiency values, determined by the current-voltage curve (I-V curve) analysis of mini solar modules before and after durability evaluation according to the introduction of luminescent aluminum hydroxide, respectively.

TABLE 2
Before accelerated weathering (t = 0)

| | | Jsc | FF | Efficiency | Efficiency |
|---|---|---|---|---|---|
| | V_{oc} | (mA/cm²) | (%) | (%) | (%) |
| Example 1 | 0.622 | 35.72 | 0.79 | 17.55 | 2.33 |
| Example 2 | 0.621 | 35.89 | 0.79 | 17.61 | 2.68 |
| Comparative | 0.620 | 35.01 | 0.79 | 17.15 | Reference |
| Example 1 | | | | | |
| Comparative | 0.621 | 34.81 | 0.79 | 17.08 | −0.41 |
| Example 2 | | | | | |
| Comparative | 0.622 | 34.61 | 0.79 | 17.01 | −0.81 |
| Example 3 | | | | | |
| Comparative | 0.621 | 34.10 | 0.79 | 16.83 | −2.45 |
| Example 4 | | | | | |

In table 2, before weathering degradation, the solar modules using the encapsulant (EVA-AlOH 0.1) of Example 1 and the encapsulant (EVA-AlOH 0.5) of Example 2, in which luminescent aluminum hydroxide was introduced, showed 2.33 and 2.68% improvement in relative efficiency, compared to the module using the encapsulant in which EVA alone was used. That is, it can be seen that, by introducing luminescent aluminum hydroxide, the initial efficiency of a solar module increases according to the increase in short-circuit current density by down-conversion of ultraviolet absorption and visible photoluminescence.

TABLE 3
After UV aging test (t = 2000 hrs)

| | | Jsc | FF | Efficiency | Efficiency |
|---|---|---|---|---|---|
| | V_{oc} | (mA/cm²) | (%) | (%) | (%) |
| Example 1 | 0.621 | 35.69 | 0.78 | 17.29 | 3.35 |
| Example 2 | 0.621 | 35.82 | 0.78 | 17.33 | 3.59 |
| Comparative | 0.621 | 34.54 | 0.78 | 16.73 | −Reference |
| Example 1 | | | | | |
| Comparative | 0.62 | 34.59 | 0.78 | 16.72 | 0.12 |
| Example 2 | | | | | |
| Comparative | 0.621 | 34.48 | 0.78 | 16.70 | −0.18 |
| Example 3 | | | | | |
| Comparative | 0.621 | 34.05 | 0.78 | 16.49 | −1.43 |
| Example 4 | | | | | |

In addition, according to Table 3, with regard to changes in the efficiency after exposing the specimens in the UV aging test for 2000 hours, the solar modules using the encapsulant (EVA-AlOH 0.1) of Example 1 and the encapsulant (EVA-AlOH 0.5) of Example 2, in which luminescent aluminum hydroxide was introduced, showed 3.35 and 3.59% improvement in relative efficiency, compared to the module using the encapsulant in which EVA alone was used. That is, as described above with reference to FIG. 9, in the case of the EVA-alone encapsulant (Comparative Example 1), the transmittance of the EVA encapsulant layer decreases according to the UV aging, and thus the photocurrent conversion efficiency of the solar cell under the encapsulant is reduced, while in the cases of the EVA-AlOH 0.1 and EVA-AlOH 0.5 encapsulants, the same transmittance levels as before the UV aging, were maintained, thereby preventing the output of the solar cell from degrading. In addition, in Comparative Examples 2 to 4, Chimassorb 81 (2-hydroxy-4-octyloxy-benzophenone) manufactured by Ciba was added as a UV absorber to EVA, respectively, but the efficiencies of the EVA-C81 0.1, 0.2, and 0.5 were 0.12%, −0.18%, and −1.43%, respectively, compared to the EVA-alone encapsulant (Comparative Example 1), suggesting that unfavorable results were obtained, compared to Examples. It can also be seen that undesirable results were obtained when the encapsulants of Comparative Examples 2 and 4 having the same content as the luminescent aluminum hydroxide in Examples 1 and 2 of the present invention were used.

TABLE 4
After damp-heat test (t = 2000 hrs)

| | | Jsc | FF | Efficiency | Efficiency |
|---|---|---|---|---|---|
| | V_{oc} | (mA/cm²) | (%) | (%) | (%) |
| Example 1 | 0.619 | 35.57 | 0.75 | 16.51 | 5.43 |
| Example 2 | 0.619 | 35.72 | 0.75 | 16.58 | 5.87 |
| Comparative | 0.618 | 34.25 | 0.74 | 15.66 | Reference |
| Example 1 | | | | | |
| Comparative | 0.619 | 34.18 | 0.74 | 15.65 | −0.06 |
| Example 2 | | | | | |
| Comparative | 0.619 | 34.01 | 0.74 | 15.58 | −0.51 |
| Example 3 | | | | | |
| Comparative | 0.619 | 33.95 | 0.74 | 15.55 | −0.70 |
| Example 4 | | | | | |

In addition, as can be seen from Table 4, with regard to changes in the efficiency after exposing the specimens in the damp-heat aging test for 2000 hours, the solar modules using the encapsulant (EVA-AlOH 0.1) of Example 1 and the encapsulant (EVA-AlOH 0.5) of Example 2, in which luminescent aluminum hydroxide was introduced, showed 5.43 and 5.87% improvement in relative efficiency, compared to the module using the encapsulant in which EVA alone was used. The relative efficiency values according to the introduction of the luminescent aluminum hydroxide showed larger differences in the damp-heat aging test results than in the UV aging test because the EVA encapsulant showed severer deterioration in the damp-heat aging test than in the UV aging test, and the transmittance of the encapsulant layer could be maintained by preventing deterioration by the introduction of luminescent aluminum hydroxide. As described above, the present invention provides a technology in which when a solar cell and a solar module are formed by dispersing luminescent aluminum hydroxide in a solar encapsulant, the transmittance of an encapsulant layer is maintained by improving the durability of the encapsulant, thereby improving the long-term durability of the solar cell and solar module and ensuring the amount of power generation by minimizing a reduction in the output over time.

### Examples 3-6: Manufacture of Encapsulant Sheet Containing Solar Wavelength Conversion Material

Each of the aluminum hydroxide solutions prepared in Preparation Examples 2 and 4 (Examples 3 and 4) and the aluminum hydroxide solutions prepared in Preparation Examples 1 and 3 (Examples 5 and 6) was applied to the surface of a 6-inch polycrystalline solar cell by using a spray coating method so as to be located at the interface between the silicon cell and the encapsulant. Glass/encapsulant layer/photovoltaic (PV) cell/encapsulant layer/back sheet were stacked in that order from the front surface where light is incident, and the silicon solar cell module may then be manufactured through lamination. In the manufactured solar cell module, near-infrared luminescent aluminum hydroxide is placed at the interface between the encapsulant and the solar cell. The compositions of solar wavelength conversion materials constituting the solar cell are shown in Table 5, and each 50 mg was included.

### Comparative Example 5: Manufacture of Solar Cell Containing Luminescent Aluminum Hydroxide

For comparison, a simple mixed solution of 50 mg of luminescent aluminum hydroxide prepared alone as an aluminum hydroxide precursor and 0.1 mg of lanthanide ion ytterbium (III) acetate hydrate was spray-coated on the surface of a silicon cell. A solar cell was prepared in the same manner as in Example 3, except that a simple mixed solution of luminescent aluminum hydroxide and ytterbium (III) acetate hydrate was prepared.

TABLE 5
(Unit: mg/ml)

| | | | | | Comparative |
|---|---|---|---|---|---|
| | Example 3 | Example 4 | Example 5 | Example 6 | Example 5 |
| Solar wavelength | AIOH-Yb | AIOH-NA-Yb | AIOH | AIOH-NA | AIOH, ytterbium |
| conversion material | | | | | (III) acetate hydrate |

### Experimental Example 2: Performance Evaluation of Solar Cell Containing Solar Wavelength Conversion Material

In order to analyze the change in the solar cell efficiency according to the introduction of luminescent aluminum hydroxide, a solar simulator (WXS-156S-10) manufactured by WACOM was used. In addition, in order to measure the total reflectance according to the aluminum hydroxide coating, UV-3600 NIR (with MPG-3100) manufactured by Shimadzu was used, and the change before and after coating was analyzed.

Table 6 shows the results of measuring the efficiency of a 6-inch polycrystalline silicon solar cell coated with luminescent aluminum hydroxide. In order to increase the precision of the efficiency measurement, all solar cell efficiencies were measured before the aluminum hydroxide was applied and then compared with the results after the aluminum hydroxide was applied. The following solar cells 1 to 5 are solar cells manufactured under the same conditions as the solar cells of the corresponding Examples and Comparative Examples without including the solar wavelength conversion material, respectively.

TABLE 6

| | | Short-circuit | | Maximum | | Efficiency |
|---|---|---|---|---|---|---|
| | Open-circuit | current | | power | | (Relative |
| | voltage | density | FF | (Pmax) | Efficiency | efficiency |
| | (V) | (mA/cm²) | (%) | (W) | (%) | change) |
| Solar cell #1 | 0.620 | 34.70 | 78.98 | 4.155 | 17.07 | — |
| Example 3 | 0.624 | 35.84 | 79.03 | 4.301 | 17.67 | +0.60 |
| | | | | | | (3.51%) |
| Solar cell #2 | 0.624 | 34.59 | 78.96 | 4.147 | 17.04 | — |
| Example 4 | 0.624 | 36.31 | 79.01 | 4.356 | 17.90 | +0.86 |
| | | | | | | (5.04%) |
| Solar cell #3 | 0.620 | 35.03 | 79.26 | 4.189 | 17.21 | — |
| Example 5 | 0.620 | 35.45 | 79.35 | 4.245 | 17.44 | +0.23 |
| | | | | | | (1.33%) |
| Solar cell #4 | 0.622 | 34.81 | 79.16 | 4.171 | 17.14 | — |
| Example 6 | 0.622 | 35.59 | 79.18 | 4.266 | 17.53 | +0.39 |
| | | | | | | (2.27%) |
| Solar cell #5 | 0.620 | 34.86 | 79.25 | 4.168 | 17.12 | — |
| Comparative | 0.620 | 35.31 | 79.2 | 4.211 | 17.34 | +0.22 |
| Example 5 | | | | | | (1.29%) |

In Table 6, when luminescent aluminum hydroxides AlOH, AlOH-NA, AlOH—Yb, and AlOH-NA-Yb were applied, the short-circuit current density and the efficiency were both increased, compared to uncoated silicon solar cells. The relative efficiency changes for the AlOH, AlOH-NA, AlOH—Yb, and AlOH-NA-Yb were 1.33%, 2.27%, 3.51%, and 5.04%, respectively, which were better than those for AlOH and AlOH-NA, which were doped with Yb to enable near-infrared photoluminescence. Specifically, it was confirmed that when 2-naphthoic acid was doped together with Yb, the relative efficiency increased more significantly than when only Yb was doped.

In addition, in Comparative Example 5, when a solar cell was manufactured by spray-coating a mixed solution of luminescent aluminum hydroxide (AlOH) and lanthanide ion ytterbium (III) acetate hydrate synthesized with a single aluminum hydroxide precursor on the surface of a silicon cell, it was confirmed that the relative efficiency increased by 1.29%, which is similar to the result of Comparative Example 5 in which only luminescent aluminum hydroxide was coated. This is because effective energy transfer from luminescent aluminum hydroxide to Yb ions did not occur, and thus only the down-conversion effect of luminescent aluminum hydroxide was realized, by which the light conversion effect of the luminescent aluminum hydroxide according to the present invention was clearly confirmed.

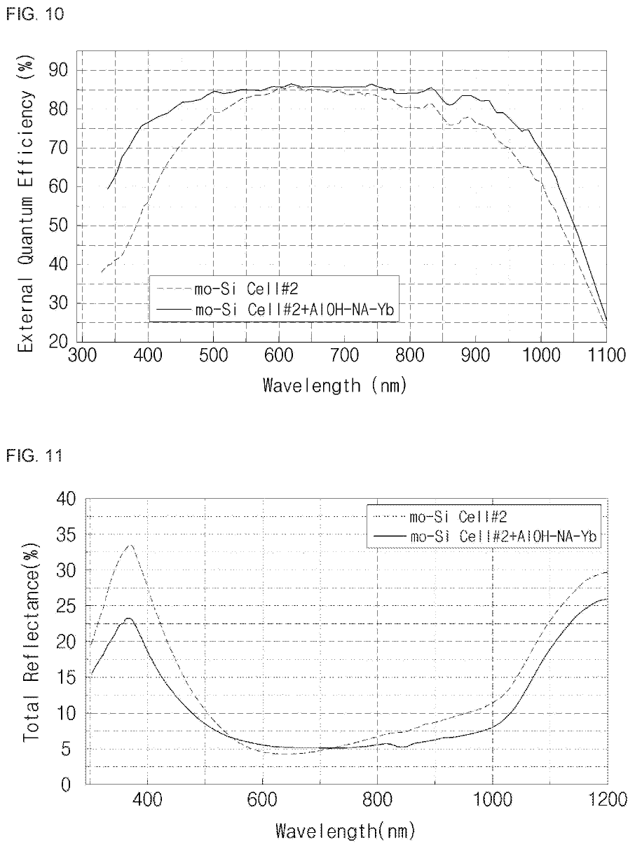

In order to verify such increases in efficiency, the photocurrent conversion efficiencies (or external quantum efficiency) before and after luminescent aluminum hydroxide coating were measured, and FIG. 10 shows the result of measuring the external quantum efficiency changes of a solar cell #2 of Table 6 and an AlOH-NA-Yb-coated cell of Example 4.

In FIG. 10, the dotted line represents the external quantum efficiency spectrum of the solar cell #2 of Table 6, and the solid line represents the external quantum efficiency spectrum of the AlOH-NA-Yb-coated cell of Example 4. In addition, it can be seen that the conversion efficiency was greatly increased by down-conversion after the Yb coating from 300 nm to around 500 nm.

FIG. 11 shows the result of measuring the total reflectance change of the solar cell #2 of Table 6 and the AlOH-NA-Yb coated cell of Example 4. The dotted line represents the total reflectance before coating near-infrared photoluminescent aluminum hydroxide, and the solid line represents the reflectance spectrum after coating AlOH-NA-Yb. It can be seen that after coating, the reflectivity decreases more in the 300 to 500 nm and 800 to 1100 nm regions and the reflectance is low, which is more advantageous for solar cells. That is, by coating near-infrared luminescent aluminum hydroxide on the surface of a silicon solar cell, the short-circuit current of the silicon solar cell increased and thus the overall efficiency increased by the down-conversion effect by ultraviolet absorption and visible and near-infrared photoluminescence and the anti-reflective coating effect in which the refractive index of the near-infrared luminescent aluminum hydroxide has a value between the refractive index of the silicon solar cell surface and the refractive index of the encapsulant (1.5<n_{aluminum hydroxide}<2.5), and thus the entry of light into the silicon solar cell is facilitated.

The present invention provides a technology in which when a solar cell and a solar module are formed by dispersing luminescent aluminum hydroxide in a solar encapsulant, the transmittance of an encapsulant layer is maintained by improving the durability of the encapsulant, thereby improving the long-term durability of the solar cell and solar module and ensuring the amount of power generation by minimizing a reduction in the output over time.

### Examples 7-12: Manufacture of Encapsulant Sheet Containing Solar Wavelength Conversion Material

A 6-inch polycrystalline silicon solar cell was used.

The solar wavelength conversion material solution prepared according to Preparation Example 3 was applied to the surface of the 6-inch silicon cell by using a spray coating method to be located at the interface between the silicon solar cell and the encapsulant.

Glass/encapsulant layer/solar wavelength conversion material/solar cell/encapsulant layer/back sheet were stacked in that order from the front surface where light is incident, and the silicon solar cell module may then be manufactured through lamination. In the manufactured solar cell module, luminescent aluminum hydroxide was placed at the interface between the encapsulant and the solar cell. As the composition of the solar wavelength conversion material constituting the solar cell, the luminescent aluminum hydroxide prepared in the above-described method was used, and in these Examples, the solar conversion material prepared by adding an aromatic ring compound was used, and in Examples 10 to 12, solar cells were prepared in the same manner as in Examples 7 to 9, respectively, except that only luminescent aluminum hydroxide was used without including an aromatic ring compound. The contents of the solar wavelength conversion material are shown in Table 7 below.

TABLE 7
(Unit: mg/ml)

| | Example | Example | Example | Example | Example | Example |
|---|---|---|---|---|---|---|
| | 7 | 8 | 9 | 10 | 11 | 12 |
| Solar wavelength | 8.3 | 16.6 | 20 | 8.3 | 16.6 | 20 |
| conversion material | | | | | | |

### Comparative Example 6

A solar cell was manufactured in the same manner as in Example 7, except that a coating composition was prepared by simply mixing and dispersing an aluminum hydroxide precursor (20 mg/ml) and an aromatic ring compound 3-hydroxyl-2-naphthoic acid (2 mg/ml) in the same amount as in Example 7 and was then placed on the light-receiving side of a solar cell material.

### Experimental Example 3: Performance Evaluation of Solar Cell Containing Solar Wavelength Conversion Material

In order to analyze the change in the solar cell efficiency according to the introduction of luminescent aluminum hydroxide, a solar simulator (WXS-156S-10) manufactured by WACOM was used, efficiency changes before and after coating aluminum hydroxide and before and after thermal lamination were all measured. In addition, in order to analyze the external quantum efficiency for each wavelength, IPCE (QEX10) equipment manufactured by PV Measurement was used, and the changes in the conversion efficiency before and after coating aluminum hydroxide were observed. Additionally, UV-3600 NIR (with MPC-3100) manufactured by Shimadzu was used for measuring the total reflectance according to the aluminum hydroxide coating, and the changes before and after coating were analyzed.

Table 8 shows the results of measuring the efficiency of a 6-inch polycrystalline silicon solar cell coated with luminescent aluminum hydroxide. In order to increase the precision of the efficiency measurement, all solar cell efficiencies were measured before the aluminum hydroxide was applied, and then compared with the results after the aluminum hydroxide was applied. The following solar cells 5 to 11 are solar cells manufactured under the same conditions as the solar cells of the corresponding Examples and Comparative Examples without including the solar wavelength conversion material, respectively.

TABLE 8

| | | | | Maximum | | Efficiency |
|---|---|---|---|---|---|---|
| | Open-circuit | Short-circuit | | power | | (Relative |
| | voltage | current density | FF | Pmax | Efficiency | efficiency |
| | (V) | (mA/cm²) | (%) | (W) | (%) | change) |
| Solar cell #5 | 0.622 | 34.81 | 79.16 | 4.171 | 17.14 | |
| Example 7 | 0.622 | 35.59 | 79.18 | 4.266 | 17.53 | +0.39 |
| | | (2.24%↑) | | | | (2.27%) |
| Solar cell #6 | 0.622 | 34.64 | 79.24 | 4.155 | 17.07 | |
| Example 8 | 0.622 | 35.53 | 79.28 | 4.264 | 17.52 | +0.45 |
| | | (2.57%↑) | | | | (2.63%) |
| Solar cell #7 | 0.624 | 34.59 | 78.96 | 4.147 | 17.04 | |
| Example 9 | 0.624 | 35.48 | 79.08 | 4.261 | 17.51 | +0.47 |
| | | (2.57%↑) | | | | (2.76%) |
| Solar cell #8 | 0.620 | 35.03 | 79.26 | 4.189 | 17.21 | |
| Example 10 | 0.620 | 35.45 | 79.35 | 4.245 | 17.44 | +0.23 |
| | | (1.2%↑) | | | | (1.33%) |
| Solar cell #9 | 0.622 | 34.83 | 79.71 | 4.203 | 17.27 | |
| Example 11 | 0.622 | 35.32 | 79.85 | 4.269 | 17.45 | +0.17 |
| | | (1.41%↑) | | | | (0.98%) |
| Solar cell #10 | 0.622 | 34.81 | 79.60 | 4.195 | 17.24 | |
| Example 12 | 0.622 | 35.54 | 79.27 | 4.264 | 17.52 | +0.28 |
| | | (2.10%↑) | | | | (1.62%) |
| Solar cell #11 | 0.622 | 34.92 | 79.21 | 4.187 | 17.20 | |
| Comparative | 0.622 | 35.35 | 79.25 | 4.240 | 17.43 | +0.23 |
| Example 6 | | | | | | (1.34%) |

In Table 8, when the luminescent aluminum hydroxide AlOH or AlOH-NA was applied, the short-circuit current density and the efficiency were both increased, compared to an uncoated silicon solar cell. Specifically, when AlOH-NA was applied, the short-circuit current density and the efficiency were better than when AlOH was applied.

In addition, when a solar cell was manufactured by separately adding AlOH and NA, mixing and coating (Comparative Example 6), effective energy transfer from NA to AlOH became unfeasible, and thus the desired result was not obtained.

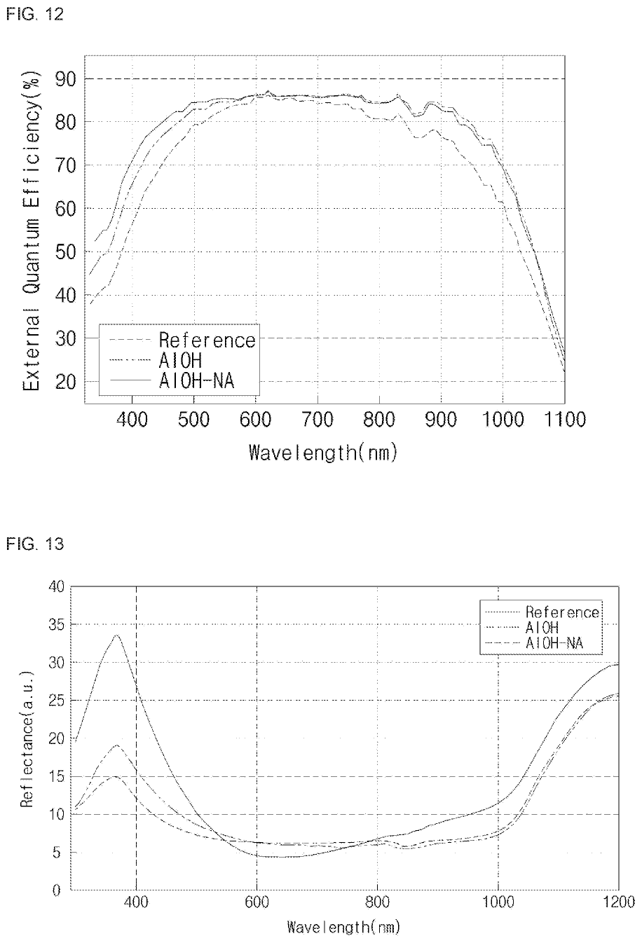

In order to verify such increases in the efficiency, incident photon-to-current efficiency (IPCE) was measured before and after aluminum hydroxide coating, and FIG. 12 shows the photocurrent conversion efficiency according to the wavelength as a result of IPCE measurement, that is, an external quantum efficiency (EQE) spectrum.

FIG. 12 shows the results of solar cells #10 (Example 12) and #7 (Example 9) in Table 8. The dotted line represents the EQE spectrum before coating, the dash-double dotted line represents EQE spectrum when coating AlOH (Example 12), and the solid line represents EQE spectrum after coating AlOH-NA (Example 9). From the result of FIG. 12, it can be seen that when the luminescent aluminum hydroxide is coated, the conversion efficiency was increased by down-conversion from 300 nm to around 500 nm, and more effective down-conversion can be achieved when coating AlOH-NA than when coating AlOH.

In addition, FIG. 13 shows the results of measuring the reflectance changes of solar cells #10 (Example 12) and #7 (Example 9) in Table 8 according to luminescent aluminum hydroxide coating. The solid line represents the total reflectance before coating aluminum hydroxide, the dash-double dotted line represents the reflectance spectrum when coating AlOH, and the dotted line represents after coating AlOH-NA. After coating, it can be seen that the reflectance decreases more in the 300 to 500 nm and 800 to 1100 nm regions. Similar to the EQE spectrum, AlOH-NA has lower reflectance in the ultraviolet wavelength region than AlOH, it is advantageous for solar cells. That is, by coating luminescent aluminum hydroxide on the surface of a silicon solar cell, the short-circuit current of the silicon solar cell increases and the overall efficiency increases accordingly by the down-conversion effect by ultraviolet absorption and visible photoluminescence and the anti-reflective coating effect in which the refractive index of the near-infrared luminescent aluminum hydroxide has a value between the refractive index of the silicon solar cell surface and the refractive index of the encapsulant (1.5<n_{aluminum hydroxide}<2.5), and thus the entry of light into the silicon solar cell is facilitated.

The present invention provides a technology in which when a solar cell and a solar module are formed by dispersing luminescent aluminum hydroxide in a solar encapsulant, the transmittance of an encapsulant layer is maintained by improving the durability of the encapsulant, thereby improving the long-term durability of the solar cell and solar module and ensuring the amount of power generation by minimizing a reduction in the output over time.

1. A solar wavelength conversion material comprising luminescent aluminum hydroxide having ultraviolet absorption and visible photoluminescence characteristics.

2. The solar wavelength conversion material of claim 1, wherein the aluminum hydroxide precursor is any one of aluminum monoacetate, aluminum triacetate, aluminum diacetate, triethyl aluminum, trimethyl aluminum, aluminum alkoxide, diethyl aluminum chloride, aluminum sulfate, aluminum cyanide, aluminum nitrite, aluminum carbonate, aluminum sulfite, aluminum hydroxide, aluminum oxide, aluminum chlorate, aluminum sulfide, aluminum chromate, aluminum trichloride, aluminum perchlorate, aluminum nitrate, aluminum permanganate, aluminum hydrogen carbonate, aluminum phosphate, aluminum oxalate, aluminum hydrogen phosphate, aluminum thiosulfate, aluminum chlorite, aluminum hydrogen sulfate, aluminum dichromate, aluminum bromide, aluminum hypochlorite, aluminum chloride hexahydrate, aluminum dihydrogen phosphate, aluminum phosphite, aluminum potassium sulfate dodeca hydrate, aluminum bromate, aluminum nitride, or derivatives thereof.

3. The solar wavelength conversion material of claim 1, wherein the solar wavelength conversion material includes an Al(OH)₃, AlOOH, 5Al₂O₃.2H₂O, or Al₂O₃ structure.

4. The solar wavelength conversion material of claim 1, wherein the luminescent aluminum hydroxide has a size in a range of 1 nm to 1000 μm.

5. The solar wavelength conversion material of claim 1, wherein the luminescent aluminum hydroxide has a porous structure.

6. The solar wavelength conversion material of claim 1, further comprising a lanthanide ion or a derivative containing same.

7. The solar wavelength conversion material of claim 6, wherein the lanthanide ion is capable of emitting light in a near-infrared, ultraviolet, or visible light wavelength region.

8. The solar wavelength conversion material of claim 6, wherein a precursor of the near-infrared luminescent lanthanide ion is one or more selected from Yb (ytterbium), Nd (neodymium), Er (erbium), Ho (holmium), Tm (thulium), and derivatives containing same.

9. The solar wavelength conversion material of claim 6, wherein the lanthanide ion precursor contains an element having a photoluminescence wavelength in the visible light wavelength region.

10. The solar wavelength conversion material of claim 6, wherein the lanthanide ion or the derivative containing same is included in an amount of 0.001 to 10 parts by weight on the basis of 100 parts by weight of the aluminum hydroxide precursor.

11. The solar wavelength conversion material of claim 1, further comprising an aromatic ring compound or a derivative thereof.

12. The solar wavelength conversion material of claim 11, wherein the aromatic ring compound or the derivative thereof is located within 10 nm from the aluminum hydroxide precursor or aluminum hydroxide derived therefrom, or is formed by a covalent bond.

13. The solar wavelength conversion material of claim 11, wherein the aromatic ring compound is one or more of an aromatic hydrocarbon in which only carbons and hydrogens are bonded together, an aromatic heterocyclic compound in which some of the carbon atoms forming a ring are substituted with oxygen, nitrogen, or sulfur atoms, other than carbon, or a derivative in which some of hydrogens are substituted with functional groups in the aromatic hydrocarbon and aromatic heterocyclic compound molecules.

14. The solar wavelength conversion material of claim 11, wherein the aromatic ring compound is one or more of furan, benzbenzofuran, isobenzbenzofuran, pyrrole, indole, isoindole, thiophene, benzbenzothiophene, imidazole, benzimidazole, purine, pyrazole, indazole, oxazole, benzoxazole, oxazole isoxazole, benzoxazole isoxazole, thiazole, benzbenzothiazole, benzbenzene, naphthalene, anthracene, pyridine, quinoxaline, acridine, pyrimidine, quinazoline, pyridazine, cinnoline, phthalazine, 1,2,3-triazine, 1,2,4-triazine, 1,3,5-triazine and derivatives thereof.

15. The solar wavelength conversion material of claim 1, wherein the particle size of the solar wavelength conversion material is 0.5 nm to 500 μm.

16. The solar wavelength conversion material of claim 1, wherein the maximum absorption wavelength of the solar wavelength conversion material is 200 nm to 500 nm

17. The solar wavelength conversion material of claim 1, wherein the maximum emission wavelength of the solar wavelength conversion material is 450 nm to 1100 nm.

18. A solar cell encapsulant comprising a resin having a solar wavelength conversion material dispersed therein, wherein the solar wavelength conversion material is the solar wavelength conversion material according to claim 1.

19. The encapsulant of claim 18, wherein the encapsulant is in the form of a film having a thickness of 100 μm or less.

20. The encapsulant of claim 18, wherein the encapsulant is EVA (ethylene vinyl acetate), POE (polyolefin elastomer), cross-linked polyolefin (PO), TPU (thermal polyurethane), PVB (polyvinyl butyral), silicone, silicone/polyurethane hybrid, or ionomer.

21. The encapsulant of claim 18, wherein the solar wavelength conversion material is included in an amount of 0.0001 to 10 parts by weight, on the basis of 100 parts by weight of the resin of the encapsulant.

22. A solar cell comprising a solar wavelength conversion material located between an encapsulant on a front surface thereof where sunlight is incident and an interface of the solar cell, wherein the solar wavelength conversion material is the solar wavelength conversion material of claim 1.

23. The solar cell of claim 22, wherein the solar wavelength conversion material is coated on the front surface of the solar cell or on the back surface of the encapsulant on the front surface of the solar cell.

24. The solar cell of claim 23, wherein the coating is spray coating or screen coating.

25. The solar cell of claim 22, wherein the encapsulant of the solar cell is EVA (ethylene vinyl acetate), POE (polyolefin elastomer), cross-linked polyolefin (PO), TPU (thermal polyurethane), PVB (polyvinyl butyral), silicone, silicone/polyurethane hybrid, or ionomer.

26. A solar cell wherein the encapsulant according to claim 18 is laminated on the front and rear surfaces of the solar cell, glass is laminated on the front surface of the encapsulant located on the front surface of the solar cell, and a back sheet is laminated on the back surface of the encapsulant located on the back surface of the solar cell.
